(19) United States
(12) Patent Application Publication
(10) Pub. No.: US 2016/0363615 A1
(43) Pub. Date: Dec. 15, 2016

(54) CURRENT MEASUREMENT

(71) Applicant: Infineon Technologies AG, Neubiberg (DE)

(72) Inventor: Christian C. Arndt, Munich (DE)

(21) Appl. No.: 15/160,937

(22) Filed: May 20, 2016

(30) Foreign Application Priority Data
Jun. 11, 2015 (DE) 102015109277.8

(51) Int. Cl. G01R 17/02

(52) U.S. Cl. CPC G01R 17/02

(57) ABSTRACT

A method for measuring a load current flowing through a switch is proposed, in which a defined offset current is applied to a measurement current, in which the defined offset current is determined during at least two intervals of time during which the switch is switched on, in which the load current is determined on the basis of the defined offset current using the measurement current. A corresponding circuit is also stated.

This application claims priority to German Patent Application Number 102015109277.8, filed on Jun. 11, 2015 the entire content of which is incorporated herein by reference.

### DESCRIPTION

A method and a circuit for efficiently and accurately measuring current are presented. The object of the invention is to improve known approaches to measuring current. This object is achieved according to the features of the independent claims. Preferred embodiments can be gathered, in particular, from the dependent claims.

In order to achieve the object, a method for measuring a load current flowing through a switch is stated,
in which a defined offset current is applied to a measurement current,
in which the defined offset current is determined during at least two intervals of time during which the switch is switched on,
in which the load current is determined on the basis of the defined offset current using the measurement current.

In this case, the switch is, in particular, an electronic switch comprising a transistor (bipolar transistor, MOSFET, IGBT, etc.), for example. The switch may also comprise a plurality of electronic switches, for example a circuit breaker and a measuring switch, the circuit breaker and the measuring switch being able to be coupled to one another. For example, it is possible for the circuit breaker and the measuring switch to be in the form of MOSFETs and for their gate connections and drain connections to be connected to one another in this case. Two three-pole MOSFETs therefore result in a four-pole switch having a gate connection, a drain connection and two source connections, the measurement current, for example, being provided at the source connection of the measuring switch and a load being supplied with current, for example, via the source connection of the circuit breaker.

In this case, the load current is any desired current which flows from the switch in the direction of a consumer or a load.

The approach presented here makes it possible to flexibly and accurately measure the load current. In particular, the solution presented here may be part of a multifunctional electrical circuit comprising the switch presented here, for example. The circuit may be, for example, in the form of an integrated circuit, for example on at least one chip.

It is a development that the defined offset current is determined during the at least two intervals of time, the load current not being conducted via the path of the measurement current during these at least two intervals of time.

The defined offset current is applied to the measurement current at least temporarily, in particular permanently, during the switched-on duration of the switch.

The defined offset current is determined during the at least two intervals of time during which the switch is switched on and, in particular, the load current is not part of the measurement current.

In this case, it is noted that, in this respect, the term “defined offset current” corresponds to the impressed offset current which can be provided, for example, by a current source or (via a resistive element) by means of a voltage source.

One development involves the load current being determined on the basis of the defined offset current by virtue of the defined offset current being subtracted from the measurement current, at least when the measurement current is not determined during the at least two intervals of time.

The load current can therefore be determined whenever the switch is switched on and none of the periods predefined by the at least two intervals of time is currently involved.

In other words, there are therefore two measuring modes for determining the measurement current which are carried out at different times: sometimes the load current is not conducted via the path of the measurement current (mode I) and sometimes the load current is at least proportionately taken into account in the measurement current (mode II). The defined offset current can be determined in mode I and the load current can be determined in mode II, the defined offset current previously determined in mode I being used in mode II to correct the load current.

In this case, it is advantageous, in particular, that the defined offset current was determined close to the determination of the load current in terms of time. It can therefore be ensured that, when determining the load current, the defined offset current has not changed significantly and the determined load current therefore has a high degree of accuracy.

One development involves the defined offset current being greater than a switch-dependent offset current.

The switch-dependent offset current preferably traces back to fluctuations in the switch which are caused, for example, by the production, by temperature and/or aging. As a result of the fact that the defined offset current is greater than the switch-dependent offset current, it is possible to achieve the situation in which the measurement current is always positive irrespective of the variance in the switch-dependent offset current.

One development involves the at least two intervals of time comprising a plurality of intervals of time of the same duration.

One development involves the at least two intervals of time comprising a plurality of intervals of time of different durations.

One development involves the at least two intervals of time at least sometimes recurring regularly.

One development involves the at least two intervals of time at least sometimes recurring irregularly.

One development involves an item of information additionally being impressed on the defined offset current.

The information may be, for example, an absolute value or a value which changes over time. The information may also be coded, for example, in the form of a characteristic curve, for example a temperature dependence of the defined offset current. In principle, any form of coding or modulation can be used to impress the information on the defined offset current.

During current measurement, in addition to determining the load current during the at least two intervals of time during which the defined offset current is determined, this information can therefore also be determined or decoded.

One development involves the additional information representing a temperature dependence, with the result that a temperature can be determined on the basis of the defined offset current determined during the at least two intervals of time.

One development involves the additional information comprising an operating mode or status which is superimposed on the defined offset current and can be decoded on the basis of the defined offset current determined during the at least two intervals of time.

A circuit for measuring a load current is also proposed,
having a switch,
having a measuring unit,
the measuring unit being set up in such a manner that
   a defined offset current can be applied to a measurement current,
   the defined offset current can be determined during at least two intervals of time, the switch being switched on during the at least two intervals of time,
   the load current can be determined on the basis of the defined offset current using the measurement current.

The measuring unit is, for example, a processing unit, a control unit, a controller, for example a microcontroller, or processor, which can be used to switch and/or evaluate different current paths. In particular, the measuring unit may comprise further components, for example a comparison unit, a digitizing unit, a current source and/or a voltage source. Discrete components may also be provided in order to implement the measuring unit or parts of the latter. There are a multiplicity of possible ways of implementing the measuring unit in the manner described here. The same applies to the switch. It is also possible for the switch and the measuring unit or parts thereof to be integrated, for example on a chip or at least one silicone lamella (die).

One development involves the switch comprising at least one transistor, a MOSFET, an IGBT or any other electronic switch.

One development involves the switch comprising a circuit breaker and a measuring switch which are both coupled, with the result that a load can be connected via the circuit breaker and the measurement current can be detected via the measuring switch.

One development involves the measuring unit being set up in such a manner that the load current is not conducted via the path of the measurement current during the at least two intervals of time.

One development involves the measuring unit being set up in such a manner that the load current can be determined on the basis of the defined offset current by virtue of the defined offset current being subtracted from the measurement current, at least when the measurement current is not determined during the at least two intervals of time.

The above-described properties, features and advantages and the manner in which they are achieved are explained further in connection with the following schematic description of exemplary embodiments which are explained in more detail in connection with the drawings. In this case, identical or identically acting elements may be provided with identical reference symbols for clarity.

In the drawings:

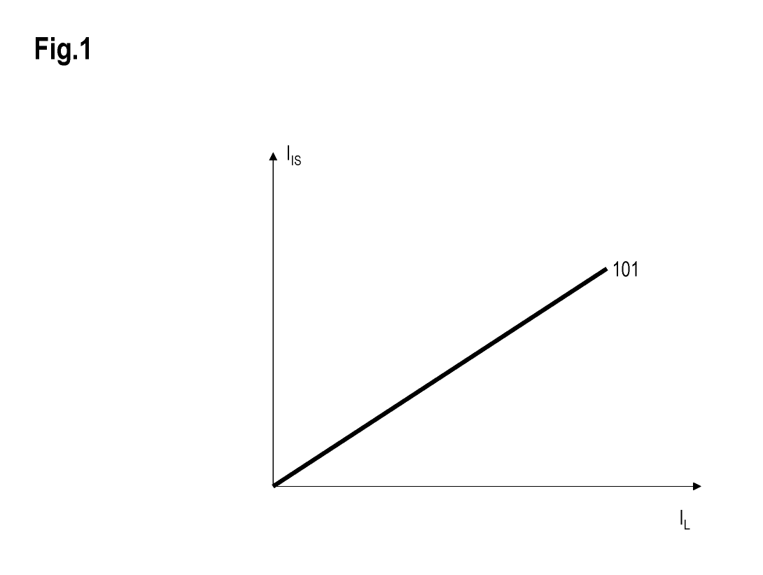

FIG. 1 shows a graph comprising an ideal characteristic curve for a target function for measuring current. According to said graph, the (measurable) measurement current is I_{IS};

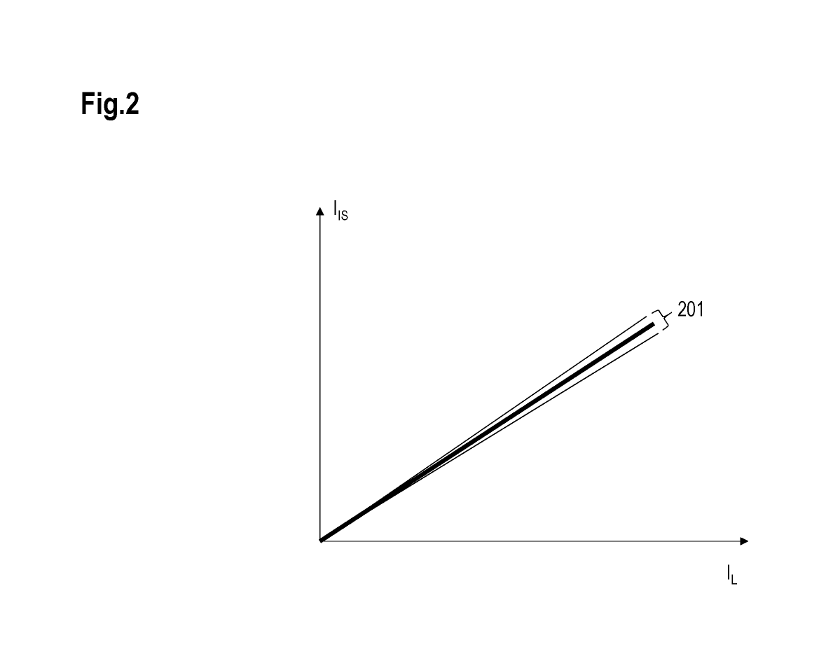

FIG. 2 shows a graph having a region in which the measurement current I_{IS} is dependent on the change in the K_{ILIS} factor;

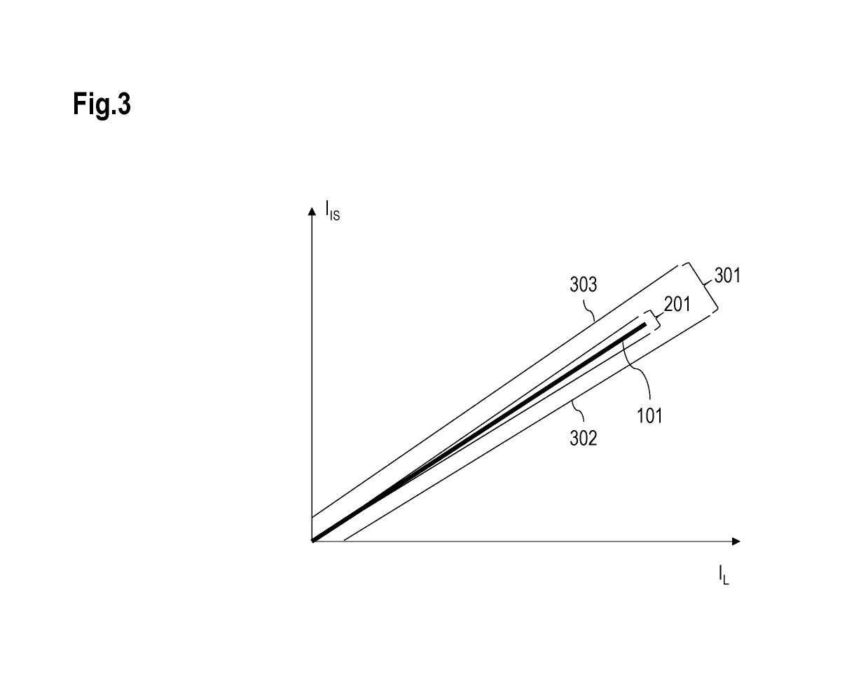

FIG. 3 shows a graph having a region for the possibly resulting measurement current I_{IS} on the basis of a varying K_{ILIS} factor and the offset current I_{IS} off mentioned above;

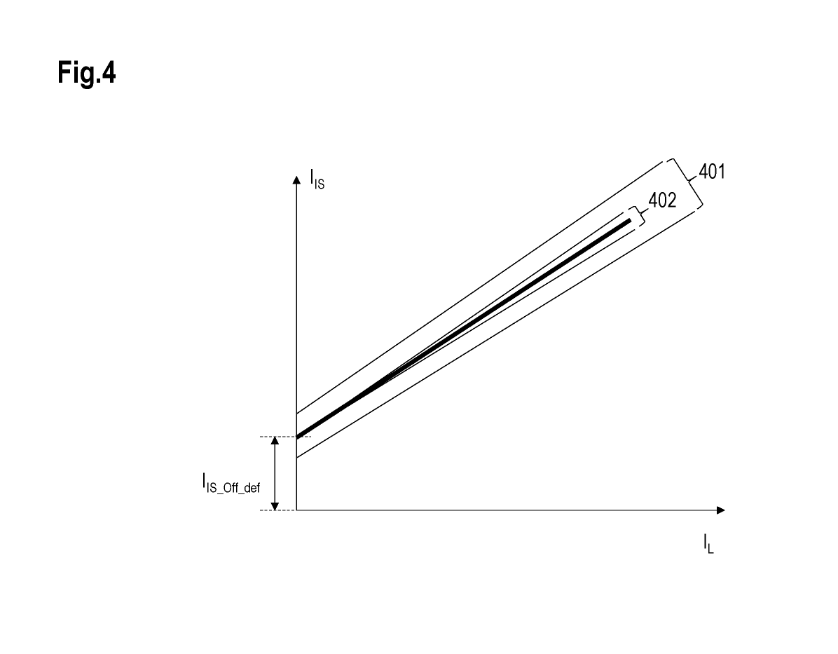

FIG. 4 shows a graph having a region which has been shifted upward in comparison with the region from FIG. 3 in the direction of the positive I_{IS} axis by a defined offset current I_{IS}_{_}_{Off}_{_}_{def};

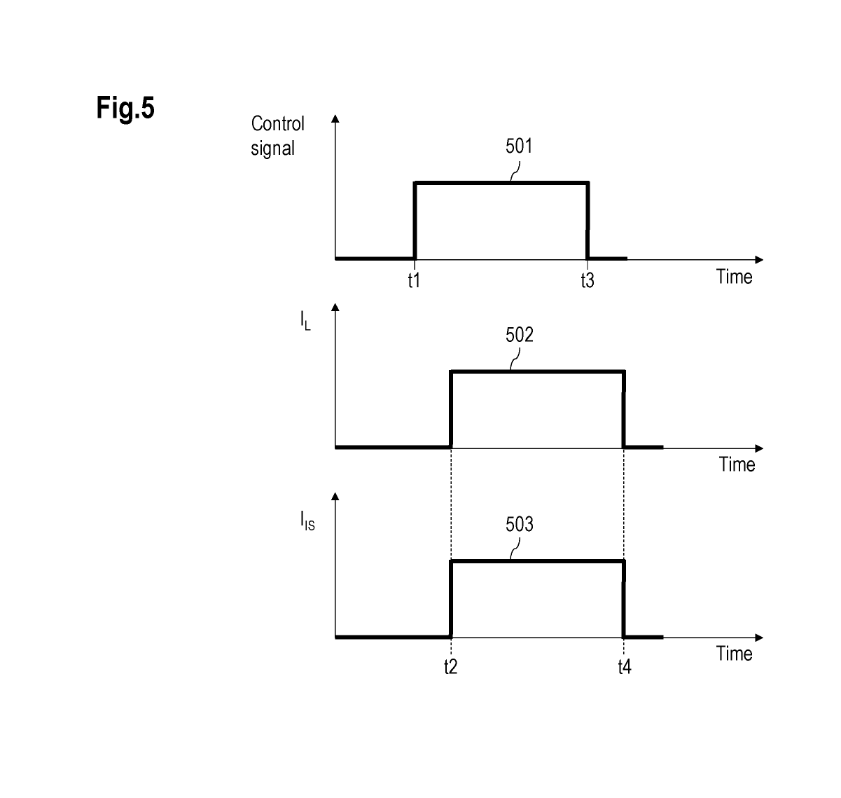

FIG. 5 shows a temporal profile of a control signal (in the form of a current signal) for an electronic switch, for example a high-side switch of a half-bridge;

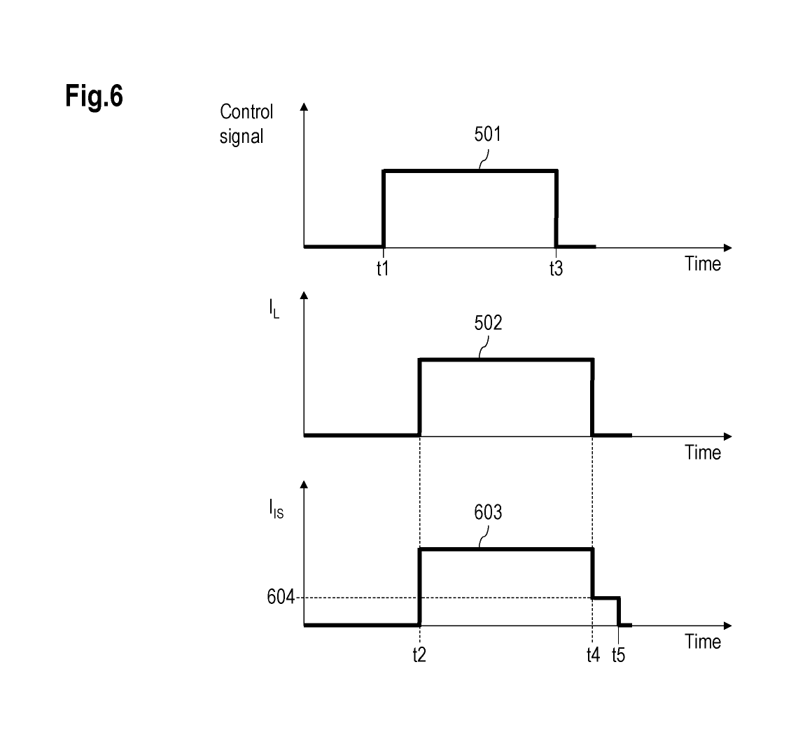

FIG. 6 shows temporal profiles of the control signal, of the current signal and of a measurement current I_{IS} for the case of an additionally provided defined offset current;

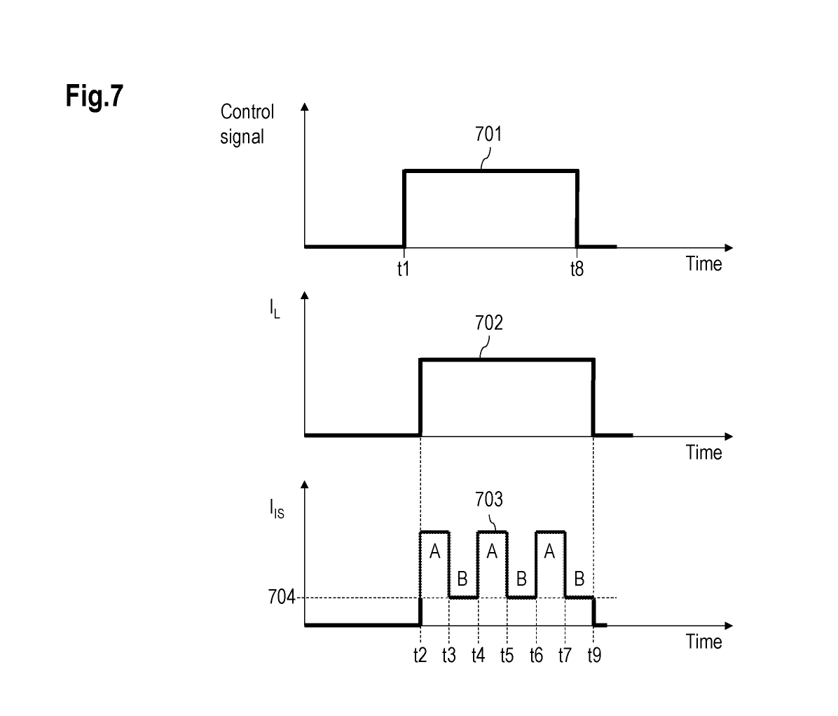

FIG. 7 shows temporal profiles of a control signal for an electronic switch, of a current signal I_{L} which is produced on the basis of the control signal at a load (load current) and of a measurement current I_{IS} based thereon;

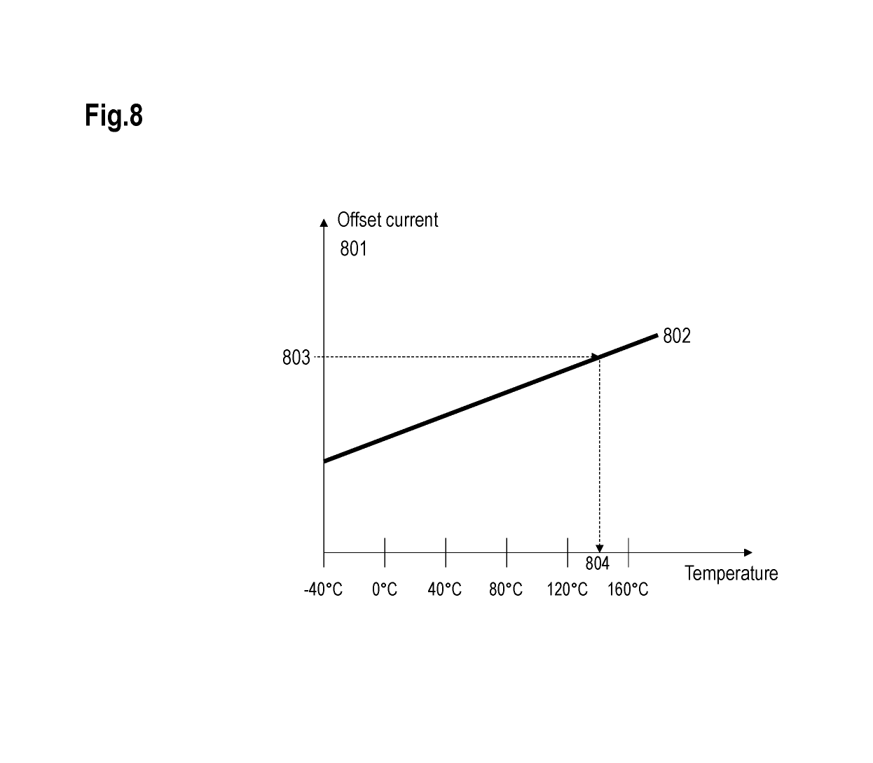

FIG. 8 shows an exemplary graph of a temperature dependence of the offset current;

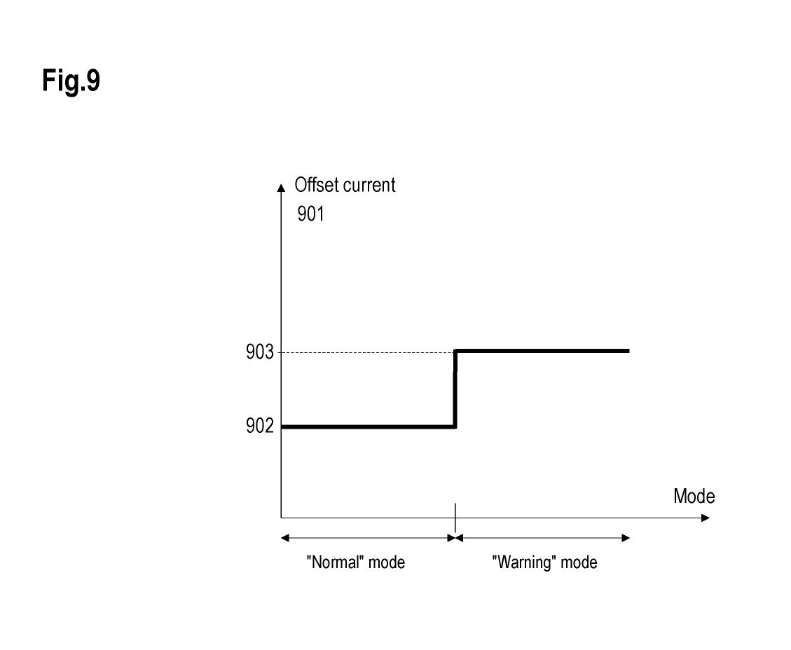

FIG. 9 shows a graph for an example of coding of two states by means of the offset current;

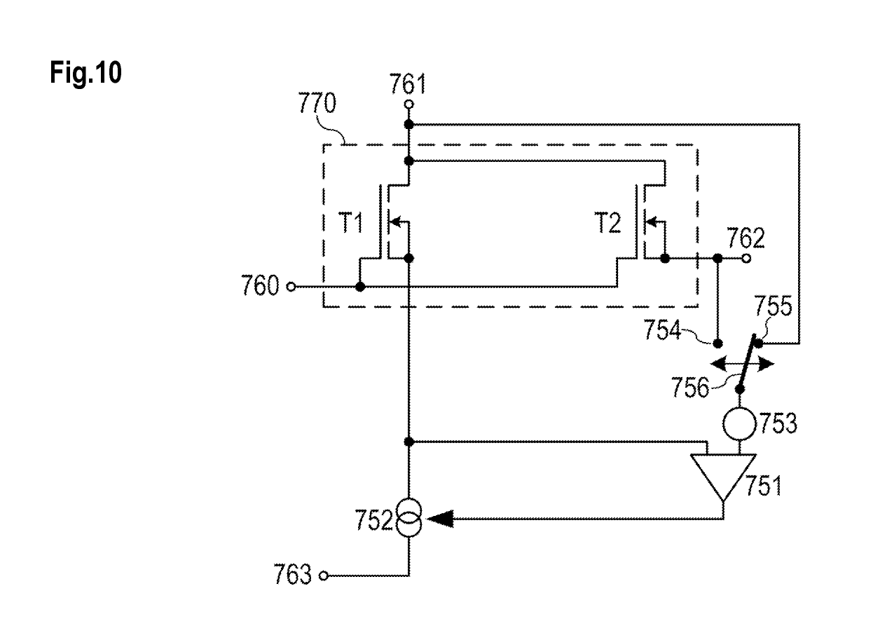

FIG. 10 shows an exemplary circuit diagram for a switch comprising a power n-channel MOSFET and a measuring n-channel MOSFET, the MOSFETs having a common gate connection and a common drain connection.

In particular, an approach for a current measuring output (also referred to as a “current sense” output) which assists with measurement of the load current over a load current range is proposed. This approach is explained below, in particular, using a so-called high-side switch but can likewise be used for so-called low-side switches or other semiconductor components.

The high-side switch is, in particular, an electronic switch, for example a transistor, one connection of which is connected to a supply voltage, whereas the low-side switch is, in particular, an electronic switch, for example a transistor, one connection of which is connected to ground. The high-side switch and the low-side switch may be part of a bridge circuit, in particular a half-bridge circuit.

For example, a current measuring accuracy is improved by virtue of a current offset being pulled to a positive value by means of a current measuring circuit and being made available to a component to be evaluated (in particular at predefined times, for example regularly or irregularly). The component to be evaluated may be, for example, a microcontroller or may comprise such a microcontroller. The microcontroller can determine the current offset, for example, as a voltage signal via a resistor, can digitize the voltage signal at one of its inputs and can internally process the voltage signal further.

A high-current switch of the type BTS50060-1TEA is known. It is proposed, in particular, to extend the functionality of such a high-current switch in such a manner that a current offset provided is varied over time.

A current measuring circuit generally pursues the aim of clearly converting the load current I_{L} to be measured into a measurable measurement current I_{IS}. FIG. 1 shows a graph comprising an ideal characteristic curve 101 for a target function for measuring current. According to said graph, the (measurable) measurement current I_{IS} is:

$${I}_{IS} = \frac{{I}_{L}}{{K}_{ILIS}} .$$

A current measuring factor K_{ILIS} denotes a relationship between the load current I_{L} and and the measurement current I_{IS}, that is to say the load current I_{L} is greater than the measurement current I_{IS} by the factor K_{ILIS}.

The current measuring circuit also experiences a variation in the K_{ILIS} factor in its target function as a result of fluctuations in the production or on account of temperature and aging effects. FIG. 2 shows a graph having a region 201 in which the measurement current I_{IS} is dependent on the change in the K_{ILIS} factor.

In addition to the change in the K_{ILIS} factor, the current measuring accuracy is also impaired by production fluctuations, temperature effects, aging effects and possibly further effects.

Such effects result in an offset which corresponds to an offset current I_{IS}_{_}_{Off} which is superimposed on the measurement current I_{IS} (that is to say is added to said measurement current or is subtracted from the latter):

$${I}_{IS} = \frac{{I}_{L}}{{K}_{ILIS}} \pm {I}_{IS\_Off}$$

FIG. 3 shows a graph having a region 301 for the possibly resulting measurement current I_{IS} on the basis of a varying K_{ILIS} factor and the offset current I_{IS}_{_}_{Off} mentioned above.

Possible accuracy for the current measurement results from boundaries of the region 301 which are indicated by lines 302 and 303. The further away from the ideal characteristic curve 101 the lines 302 and 303 are, the more inaccurate the current measurement.

In the case of the high-current switch of the type BTS50060-1TEA, it is known that the offset is distorted to a positive measurement current. FIG. 4 shows a diagram having a region 401 which has been shifted upward in comparison with the region 301 from FIG. 3 in the direction of the positive I_{IS} axis by a value I_{IS}_{_}_{Off}_{_}_{def}. In this case, it is mentioned that the deflection of the regions 301 and 401 may be different.

The measurement current I_{IS} is therefore

$${I}_{IS} = \frac{{I}_{L}}{{K}_{ILIS}} \pm {I}_{IS\_Off} + {I}_{IS\_Off \_def}$$

$$where$$

$${I}_{IS\_Off} < {I}_{IS\_Off \_def}$$

and where I_{IS}_{_}_{Off} is determined on the basis of the switch (for example by means of a measurement in advance) and I_{Is}_{_}_{Off}_{_}_{def} is known.

I_{IS}_{_}_{Off}_{_}_{def} is, by way of example, a positively distorted offset current (also referred to below as “defined offset current”).

This defined offset current can now be made available to the component to be evaluated, for example the microcontroller. This microcontroller therefore receives the measurement current with a load current portion and the defined offset current and, with knowledge of the defined offset current, can determine the load current from the K_{ILIS} factor since fluctuations can be reduced by the defined offset current or can be largely or else completely removed by calculation.

A region 401 of the inaccuracy, which takes into account the offset current I_{IS}_{_}_{Off}, is therefore reduced to a region 402 since the individual offset current I_{IS}_{_}_{Off} of each switch can be measured and can therefore be taken into account in the overall calculation.

FIG. 5 shows, by way of example, a temporal profile of a control signal 501 (in the form of a current signal) for an electronic switch, for example a high-side switch of a half-bridge. The control signal 501 is switched on at a time t1 and the control signal 501 is switched off at a time t3.

A current signal I_{L} 502 at a load follows the control signal 501 with a time delay, that is to say the current signal 502 is switched on at a time t2 and is switched off at a time t4. The delay between the times t2 and t1 and between the times t4 and t3 is due to the fact that the load current I_{L} begins to flow only after a delay between the switching-on of the switch (corresponding delay also applies to the switching-off of the switch).

FIG. 5 also shows the dependent profile of a measurement current I_{IS} 503. The measurement current 503 follows the current signal 502 in terms of time. In this case, the level of the measurement current 503 is determined from the current signal 502 using a predefined divider ratio.

FIG. 5 therefore shows the situation without a defined offset current I_{IS}_{_}_{Off}_{_}_{def}.

In contrast to FIG. 5, FIG. 6 shows, by way of example, the temporal profiles of the control signal 501, of the current signal 502 and of a measurement current I_{IS} 603 for the case of an additionally provided defined offset current.

In contrast to FIG. 5, the measurement current I_{IS} 603 does not fall to zero at the time t4, but rather still remains at a level 604 corresponding to the level of the defined offset current I_{IS}_{_}_{off}_{_}_{def} for a defined time until a time t5. The measurement current I_{IS} 603 can therefore be determined in the form of the load current I_{L} with a predefined K_{ILIS} factor and a defined offset current between the times t2 and t4. The load current I_{L} is equal to zero between the times t4 and t5 and the measurement current I_{IS} 603 for this period is therefore:

I_{IS}=I_{IS}_{_}_{Off}+I_{IS}_{_}_{Off}_{_}_{def}.

Since the switch-dependent offset current I_{IS}_{_}_{Off} is known, the defined offset current I_{IS}_{_}_{Off}_{_}_{def} can be determined by means of the measurement (simple conversion of the above equation):

I_{IS}_{_}_{Off}_{_}_{def}=I_{IS}−I_{IS}_{_}_{Off}.

It is proposed, in particular, to improve the quality or accuracy of the current measurement.

It is therefore proposed, for example, to determine the defined offset current I_{IS}_{_}_{Off}_{_}_{def} more frequently. In particular, the defined offset current I_{IS}_{_}_{Off}_{_}_{def} can be determined close to the measurement of the load current in terms of time.

For example, the defined offset current I_{IS}_{_}_{Off}_{_}_{def} can be determined regularly or irregularly, for example with a constant or variable frequency. In particular, it is possible to determine the defined offset current I_{IS}_{_}_{Off}_{_}_{def} in an independent or automated manner without special additional connections or instructions being required for this purpose.

The defined offset current may therefore possibly have a clear dependence on external states, for example temperature or supply fluctuations. Frequently determining the offset current makes it possible to achieve an improved measurement by virtue of the load current I_{L} accordingly being determined with higher accuracy using the more up-to-date offset current I_{IS}_{_}_{Off}_{_}_{def}. In particular, the situation in which the defined offset current I_{IS}_{_}_{off}_{_}_{def} is measured rarely, that is to say with a long delay with respect to the measurement of the current I_{IS}, and the defined offset current is therefore obsolete or out of date is therefore effectively prevented. This may apply, in particular, to switches which are operated at a low switching frequency and which are either switched on or switched off for a relatively long duration, for example.

Like the entire measurement current, the defined offset current is subject to fluctuations. The defined offset current is therefore a portion of the measurement current which distorts the latter. However, the load current can be determined with greater accuracy by subtracting the defined offset current from the measurement current.

FIG. 7 shows, by way of example, the temporal profile of a control signal 701 for an electronic switch, the temporal profile of a current signal I_{L} 702 which is produced on the basis of the control signal 701 at a load (that is to say a load current) and the temporal profile of a measurement current I_{IS} 703 based thereon.

The electronic switch, for example a high-side switch of a half-bridge, is switched on at a time t1 and this switch is switched off at a time t8 (compare control signal 701). The load is supplied with current (compare current signal I_{L} 702) from a time t2 to a time t9 with a time delay with respect to the control signal 701.

The signal of the measurement current I_{IS} 703 results from the current signal I_{L} 702, the signal of the measurement current I_{IS} 703 determining only a defined offset current 704 for at least a duration during the time in which the current signal I_{L} 702 supplies the load. FIG. 7 shows, by way of example, three intervals of time B, that is to say between times t3 and t4, t5 and t6 and t7 and t9, during which only the defined offset current 704 is respectively determined. Said figure also illustrates three intervals of time A during which the current signal I_{L} 702 supplies the load. The measurement current I_{IS} 703 is therefore determined in the form of the load current I_{L} 702 with a predefined K_{ILIS} factor and a defined offset current during the intervals of time from t2 to t3, from t4 to t5 and from t6 to t7 according to the relationship stated above

$${I}_{IS} = \frac{{I}_{L}}{{K}_{ILIS}} \pm {I}_{IS\_Off} + {I}_{IS\_Off \_def}$$

In this case, it is noted that a different number of intervals of time A and/or B of constant or varying length may be provided between the times t2 and t9.

The measurement current I_{IS} is therefore measured during the measuring intervals A, the load current (or part of the load current) being included in the measurement. In contrast, during the measuring intervals B, the load current is not included in the determination of the measurement current I_{IS}. This can be achieved by virtue of the load current not being conducted via the measurement path of the measurement current I_{IS} during the measuring intervals B.

FIG. 10 shows an exemplary circuit diagram for a switch 770 comprising a power n-channel MOSFET T2 and a measuring n-channel MOSFET T1. The two MOSFETs T1 and T2 may be in the form of a chip, the MOSFETs T1 and T2 having a common gate connection 760 and a common drain connection 761.

The source connection of the MOSFET T1 is connected, via a controllable current source 752 (series current regulator), to a connection 763 at which the measurement current I_{IS} is provided. The source connection of the MOSFET T2 is connected to a connection 762 to which the load can be connected. The load current I_{L} then flows via the connection 762.

The controllable current source 752 receives its control signal via the output of a comparator 751. The comparator 751 compares the voltage at the source connection of the MOSFET T1
either with the drain connection 761 plus the defined offset current (indicated by an offset voltage source 753)
or with the source connection 762 of the MOSFET T2 plus the defined offset current.

The defined offset current is provided in FIG. 10 by the offset voltage source 753 which is connected upstream of the corresponding input of the comparator. The comparator 751 regulates the current from the current source 752 on the basis of a voltage difference.

The different comparison operations by the comparator which are mentioned above can be set by means of a changeover switch 756 by virtue of that input of the comparator 751 which is connected via the voltage source 753 being connected either to a node 754 or to a node 755. The node 754 is connected to the source connection of the MOSFET T2 and the node 755 is connected to the drain connection.

If the node 755 is connected to the input of the comparator 751 via the voltage source 753, the comparator 751 experiences a distortion. In this case, the potential at the source connection of the MOSFET T1 is preferably always lower than the potential at the source connection of the MOSFET T2.

The measurement current I_{IS} 703 can be provided, for example, in the form of an alternating signal, while the load is supplied with energy via the connection 762. In particular, the measurement current I_{IS} 703 can be provided in this case at a pin (connection) alternately as
a proportional load current I_{L} 702 with a defined offset current or
as a defined offset current without a portion of the load current I_{L} 702.

With knowledge of the defined offset current and the K_{ILIS} factor, it is possible to determine the load current I_{L} 702 using the measurement current I_{IS} 703. For example, the load current I_{L} 702 can be determined using a microcontroller.

It is optionally possible to alternately change over between a proportional load current I_{L} 702 with a defined offset current and a defined offset current without a portion of the load current I_{L} 702 at a predefined frequency. Such a frequency may be 1 kHz or less, for example. In this case, a microcontroller can advantageously evaluate the alternating signals in their steady state in each case. One option is for the alternating signals to be provided for identical durations; in such a case, the so-called duty cycle (active portion) is 50% for each of the two signals.

Another option is that alternating signals can be used in order to implement (code) dependence with at least one parameter and/or at least one mode or to detect (decode) such a dependence.

If, for example, the defined offset current has a temperature dependence, the temperature of the switch and a component in the vicinity of the switch can also be inferred when evaluating the defined offset current with knowledge of the temperature dependence.

FIG. 8 shows an exemplary graph of a temperature dependence 802 of the offset current 801. If the temperature dependence 802 (for example in the form of a straight line as a characteristic curve) is known, for example through a value for the defined offset current at 25° C. or through the gradient of the straight line, the instantaneous temperature can be inferred on the basis of the instantaneous offset current 801. For example, a value 803 of an offset current is measured and an instantaneous temperature 804 is determined for this value 803.

As a result of the solution presented here, the two values of the proportional load current I_{L} with a defined offset current and of the defined offset current without a portion of the load current I_{L} are provided with a short time delay (that is to say virtually at the same time), with the result that it is also possible to determine the temperature promptly, that is to say with a slight time delay or without a significant time delay.

In principle, it is possible to also code other information. For example, error information, warnings or operating modes can be coded using the defined offset current. The defined offset current could therefore be pre-distorted further, for example upon reaching a warning state.

FIG. 9 shows a graph for an example of coding of two states by means of the offset current.

In the example shown in FIG. 9, the defined offset current 901 jumps from a value 902 to a value 903 as soon as an operating mode changes from “normal” to “warning” in an integrated circuit, for example. In other words, an additional item of information can be coded in the value of the offset current 901 and is then accordingly decoded when measuring the offset current 901. A predefined action can be carried out or initiated as a result of the decoded information. For example, a warning or an error message can be output in the “warning” mode. A user or a control device can accordingly start diagnosis or can change the system to a safe state, for example can switch off the system.

In one or more examples, the functions described here can be at least partially implemented in the form of hardware, for example in the form of special hardware components or a processor. The techniques can generally be implemented in the form of hardware, processors, software, firmware or in the form of any combination thereof. If they are implemented in the form of software, the functions can be stored in the form of one or more instructions or code on a computer-readable medium or can be transmitted via the latter and can be executed by a hardware-based processing unit. Computer-readable media may include computer-readable storage media corresponding to a material medium, for example data storage media or transmission media, including any medium which makes it possible to transmit a computer program from one location to another, for example according to a communication protocol. In this manner, computer-readable media may correspond generally to (1) material, computer-readable storage media which are non-volatile or to (2) a communication medium, for example a signal or a carrier wave. Data storage media may be any available media which can be accessed by one or more computers or by one or more processors in order to retrieve instructions, code and/or data structures for implementing the techniques described in this disclosure. A computer program product may contain a computer-readable medium.

As an example and without restriction: such computer-readable storage media may comprise RAM, ROM, EEPROM, CD-ROM or other optical disc memories, magnetic disk memories or other magnetic storage devices, flash memories or any other medium which can be used to store desired program code in the form of instructions or data structures and can be accessed by a computer. Any connection is also correctly called a computer-readable medium, that is to say a computer-readable transmission medium. If, for example, instructions are transmitted from a website, a server or another remote source using a coaxial cable, a fiber-optic cable, a twisted pair, a DSL (Digital Subscriber Line) or wireless technologies, for example infrared, radio and microwaves, the definition of the medium comprises the coaxial cable, the fiber-optic cable, the twisted pair, the DSL or wireless technologies, for example infrared, radio and microwaves. However, it goes without saying that computer-readable storage media and data storage media do not contain any connections, carrier waves, signals or other transient media, but rather are instead directed to non-transient, material storage media. Disk and disc, as used here, include CD (Compact Disc), laser disc, optical disc, DVD (Digital Versatile Disc), floppy disk and Blu-ray disc, in which case disks normally reproduce data magnetically, while discs reproduce data optically using laser. Combinations of the options mentioned above should likewise be included in the scope of computer-readable media.

Instructions can be executed by one or more processors, for example one or more central computing units (CPU, Central Processing Unit), digital signal processors (DSPs), universal microprocessors, application-specific integrated circuits (ASICs), FPGAs (Field Programmable Gate Arrays) or other equivalent integrated or discrete logic circuits. Accordingly, the term “processor”, as used here, can relate to any of the structures mentioned above or to any other structure which is able to implement the techniques described here. In addition, in some aspects, the functionality described here can be provided in dedicated hardware and/or software modules which are designed for coding and decoding or are integrated in a combined codec. The techniques could likewise be entirely implemented in one or more circuits or logic elements.

The techniques in this disclosure may be implemented in a wide variety of devices or apparatuses, including a wireless handheld device, an integrated circuit (IC) or a set of ICs (for example a chipset). Various components, modules or units are described in this disclosure in order to emphasize functional aspects of devices which are designed to implement the techniques disclosed but do not necessarily require implementation by means of different hardware units. Rather, as has been described above, various units can be combined in a single hardware unit or can be provided as a collection of cooperating hardware units, including one or more processors in conjunction with suitable software and/or firmware, as described above.

Although various exemplary embodiments of the disclosure have been disclosed, it will emerge for experts that it is possible to make various changes and modifications which will achieve some of the advantages of the disclosure without departing from the concept and scope of protection of the disclosure. It will be obvious to average experts that other components which perform the same functions can be interchanged in a suitable manner. It should be mentioned that features which have been explained with reference to a specific figure can be combined with features from other figures even in those cases in which this has not been expressly mentioned. Furthermore, the methods in the disclosure can be implemented either in pure software forms of implementation using the suitable processor instructions or in hybrid forms of implementation which use a combination of hardware logic and software logic in order to achieve the same results. Such modifications of the concept according to the invention are intended to be covered by the accompanying claims. In other examples, the features set forth in the following claims may be combined in any combinations.

1. A method for measuring a load current flowing through a switch,
in which a defined offset current is applied to a measurement current,
in which the defined offset current is determined during at least two intervals of time during which the switch is switched on, and
in which the load current is determined on the basis of the defined offset current using the measurement current.

2. The method of claim 1, in which the defined offset current is determined during the at least two intervals of time, the load current not being conducted via the path of the measurement current during these at least two intervals of time.

3. The method of claim 2, in which the load current is determined on the basis of the defined offset current by virtue of the defined offset current being subtracted from the measurement current, at least when the measurement current is not determined during the at least two intervals of time.

4. The method of claim 1, in which the defined offset current is greater than a switch-dependent offset current.

5. The method of claim 1, the at least two intervals of time comprising a plurality of intervals of time of the same duration.

6. The method of claim 1, the at least two intervals of time comprising a plurality of intervals of time of different durations.

7. The method of claim 1, the at least two intervals of time at least sometimes recurring regularly.

8. The method of claim 1, the at least two intervals of time at least sometimes recurring irregularly.

9. The method of claim 1, in which an item of information is additionally impressed on the defined offset current.

10. The method of claim 9, in which the additional information represents a temperature dependence, with the result that a temperature can be determined on the basis of the defined offset current determined during the at least two intervals of time.

11. The method of claim 9, in which the additional information comprises an operating mode or status which is superimposed on the defined offset current and can be decoded on the basis of the defined offset current determined during the at least two intervals of time.

12. A circuit for measuring a load current, the circuit comprising:
a switch, and
a measuring unit,
wherein the measuring unit is set up in such a manner that
a defined offset current can be applied to a measurement current,
the defined offset current can be determined during at least two intervals of time, the switch being switched on during the at least two intervals of time, and
the load current can be determined on the basis of the defined offset current using the measurement current.

13. The circuit of claim 12, in which the switch comprises at least one transistor, a MOSFET, and an IGBT.

14. The circuit of claim 12, in which the switch comprises a circuit breaker and a measuring switch which are both coupled, with the result that a load can be connected via the circuit breaker and the measurement current can be detected via the measuring switch.

15. The circuit of claim 12, in which the measuring unit is set up in such a manner that the load current is not conducted via the path of the measurement current during the at least two intervals of time.

16. The circuit of claim 12, in which the measuring unit is set up in such a manner that the load current can be determined on the basis of the defined offset current by virtue of the defined offset current being subtracted from the measurement current, at least when the measurement current is not determined during the at least two intervals of time.
